(19) United States
(12) Patent Application Publication
(10) Pub. No.: US 2022/0256701 A1
(43) Pub. Date: Aug. 11, 2022

(54) METAL MEMBER EQUIPPED CIRCUIT BOARD

(71) Applicants: AutoNetworks Technologies, Ltd., Yokkaichi-shi, Mie (JP); Sumitomo Wiring Systems, Ltd., Yokkaichi, Mie (JP); Sumitomo Electric Industries, Ltd., Osaka-shi, Osaka (JP)

(72) Inventors: Shun TAKAMIZAWA, Yokkaichi-shi, Mie (JP); Koki UCHIDA, Yokkaichi-shi, Mie (JP)

(21) Appl. No.: 17/597,610

(22) PCT Filed: Jul. 1, 2020
(86) PCT No.: PCT/JP2020/025812

§ 371 Date: Jan. 13, 2022

(30) Foreign Application Priority Data
Jul. 19, 2019 (JP) 2019-133776

(51) Int. Cl. H05K 1/11; H05K 1/02

(52) U.S. Cl. CPC H05K 1/115; H05K 1/0204

(57) ABSTRACT

An object is to significantly control the position of a void in a bonding material for bonding a metal member to a circuit board. A metal member equipped circuit board includes a circuit board in which a through hole is formed; a metal member disposed in the through hole forming a gap between the metal member and an inner peripheral surface of the through hole; and a bonding member that bonds together the circuit board and the metal member, wherein in a direction following an outer periphery of the metal member, a gap between an outer peripheral surface of the metal member and the inner peripheral surface of the through hole varies, and a void is present in a portion with a widest gap between the outer peripheral surface of the metal member and the inner peripheral surface of the through hole.

### CROSS-REFERENCE TO RELATED APPLICATIONS

This application is the U.S. national stage of PCT/JP2020/025812 filed on Jul. 1, 2020, which claims priority of Japanese Patent Application No. JP 2019-133776 filed on Jul. 19, 2019, the contents of which are incorporated herein.

### TECHNICAL FIELD

The present disclosure relates to a metal member equipped circuit board.

### BACKGROUND

In JP 2018-182147A, a metal member equipped circuit board is described that is provided with a printed circuit board including a through hole, a metal member including a shaft portion that is inserted inside the through hole, and an electrically conductive bonding material for bonding together the shaft portion and an inner wall of the through hole.

There is a possibility that air bubbles form in the bonding material. Air bubbles affect the thermal conductivity from the metal member to the printed circuit board. Thus, being able to control the position of air bubbles to a degree is desirable.

In light of this, the present disclosure is directed at significantly controlling the position of a void in a bonding member for bonding a metal member to a circuit board.

### SUMMARY

A metal member equipped circuit board according to the present disclosure includes a circuit board in which a through hole is formed; a metal member disposed in the through hole in a state of forming a gap between the metal member and an inner peripheral surface of the through hole; and a bonding member that bonds together the circuit board and the metal member, wherein in a direction following an outer periphery of the metal member, a gap between an outer peripheral surface of the metal member and the inner peripheral surface of the through hole varies, and a void is present in a portion with a widest gap between the outer peripheral surface of the metal member and the inner peripheral surface of the through hole.

### Advantageous Effects of Invention

According to the present disclosure, the position of a void in a bonding material for bonding a metal member to a circuit board is significantly controlled.

### BRIEF DESCRIPTION OF DRAWINGS

FIG. 1 is a schematic plan view illustrating a metal member equipped circuit board according to a first embodiment.

FIG. 2 is a cross-sectional view taken along line II-II of FIG. 1.

FIG. 3 is an explanatory diagram illustrating the manufacturing process of the metal member equipped circuit board.

FIG. 4 is an explanatory diagram illustrating the manufacturing process of the metal member equipped circuit board.

FIG. 5 is a schematic plan view illustrating a metal member equipped circuit board according to a comparative example.

FIG. 6 is a cross-sectional view taken along line VI-VI of FIG. 5.

FIG. 7 is a schematic plan view illustrating a metal member equipped circuit board according to a second embodiment.

FIG. 8 is a cross-sectional view taken along line XIII-XIII of FIG. 7.

FIG. 9 is an explanatory diagram illustrating the manufacturing process of the metal member equipped circuit board.

FIG. 10 is an explanatory diagram illustrating an example arrangement of a metal member on a circuit board.

FIG. 11 is an explanatory diagram illustrating a metal member equipped circuit board according to a first modified example.

FIG. 12 is an explanatory diagram illustrating a metal member equipped circuit board according to a second modified example.

FIG. 13 is an explanatory diagram illustrating a metal member equipped circuit board according to a third modified example.

### DETAILED DESCRIPTION OF PREFERRED EMBODIMENTS

Firstly, embodiments of the present disclosure will be listed and described.

A metal member equipped circuit board of the present disclosure is as follows.

A metal member equipped circuit board includes a circuit board in which a through hole is formed; a metal member disposed in the through hole in a state of forming a gap between the metal member and an inner peripheral surface of the through hole; and a bonding member that bonds together the circuit board and the metal member, wherein in a direction following an outer periphery of the metal member, a gap between an outer peripheral surface of the metal member and the inner peripheral surface of the through hole varies, and a void is present in a portion with a widest gap between the outer peripheral surface of the metal member and the inner peripheral surface of the through hole. Regarding the portion with a relatively narrow gap between the outer peripheral surface of the metal member and the inner peripheral surface of the through hole, the material forming the bonding member seeps into the surfaces and enters the void. Thus, voids are unlikely to form. On the other hand, regarding the portion with a relatively wide gap between the outer peripheral surface of the metal member and the inner peripheral surface of the through hole, air bubbles tend to remain, with the remnants of the air bubbles forming voids. In this manner, the position of the voids are significantly controlled.

In the direction following the outer periphery of the metal member, an even gap region with a continuous portion with a constant gap between the outer peripheral surface of the metal member and the inner peripheral surface of the through hole and a wide region in which a gap between the outer peripheral surface of the metal member and the inner peripheral surface of the through hole is greater than the gap in the even gap region may be arranged in a mixed pattern. In the even gap region, there are as few voids as possible, and, in the wide region, voids easily form. Thus, a region with few voids and a region with many voids should be divided.

In the direction following the outer periphery of the metal member, portions with a wide gap between the outer peripheral surface of the metal member and the inner peripheral surface of the through hole may be provided evenly distributed. In the entire region around the outer periphery of the metal member, the portions with a wide gap between the outer peripheral surface of the metal member and the inner peripheral surface of the through hole are easily moved and formed.

In the direction following the outer periphery of the metal member, portions with a wide gap between the outer peripheral surface of the metal member and the inner peripheral surface of the through hole may be provided unevenly distributed.

At least a portion of the inner peripheral surface formed the through hole may be a non-continuous inner peripheral surface of a circular hole that extends through the circuit board. At least a portion of the through hole can be easily formed via a circular hole extending through the circuit board.

A specific example of a metal member equipped circuit board according to the present disclosure will be described below with reference to the drawings. Note that the present disclosure is not limited to these examples and is defined by the scope of the claims, and all modifications that are equivalent to or within the scope of the claims are included.

### First Embodiment

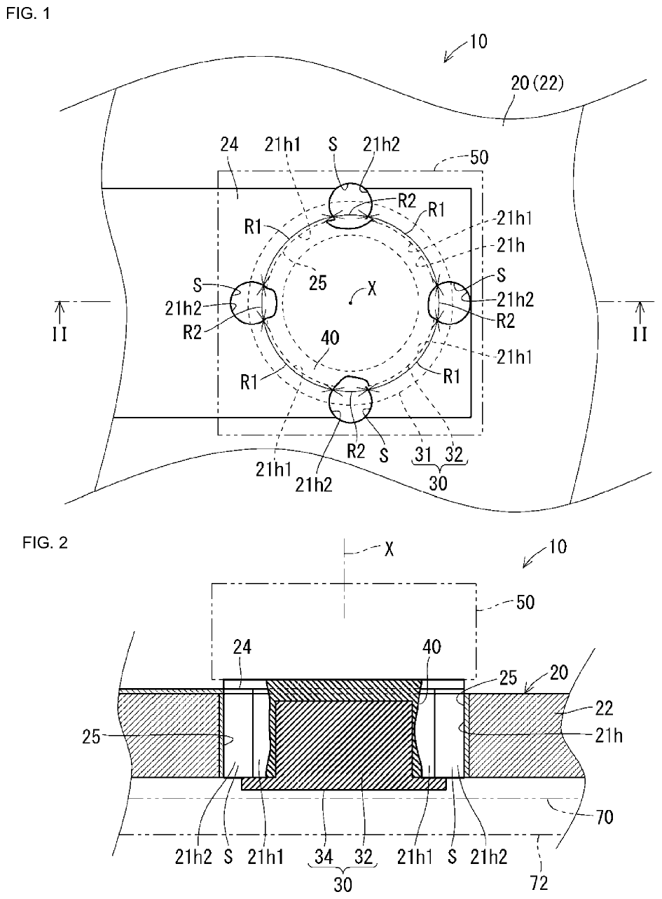

A metal member equipped circuit board according to the first embodiment will be described below. FIG. 1 is a schematic plan view illustrating a metal member equipped circuit board 10. FIG. 2 is a cross-sectional view taken along line II-II of FIG. 1. In FIGS. 1 and 2, an element 50 mounted on the metal member equipped circuit board 10 is indicated by a two-dot dash line. In FIG. 2, a heat dissipation member 72 and a thermally conductive member 70 are indicated by a two-dot dash line.

The metal member equipped circuit board 10 is a circuit board incorporated in an electrical connection box, for example. The electrical connection box, for example, is provided in an electric power supply path between a power supply and various electrical components in a vehicle, for example.

The metal member equipped circuit board 10 is provided with a circuit board 20, a metal member 30, and a bonding member 40.

The circuit board 20 is formed in a plate-like shape. A through hole 21h is formed in the circuit board 20 opening on both sides. More specifically, the circuit board 20 includes an insulating plate 22 formed of an insulating material. The through hole 21h is formed in the insulating plate 22. An electrically conductive layer 24 formed of a metal such as a copper foil is formed on a first main surface (the upper surface in FIG. 2) of the insulating plate 22. The electrically conductive layer 24 may be formed in a path forming a predetermined circuit on the first main surface of the insulating plate 22. In this example, the electrically conductive layer 24 is formed in the first main surface of the insulating plate 22 in a region surrounding the through hole 21h and is also formed extending outward from this region in one direction. The electrically conductive layer may not be formed in the other regions of the first main surface of the insulating plate 22.

An electrically conductive layer 25 is also formed on the inner peripheral surface of the through hole 21h. The electrically conductive layer 25 is connected to the electrically conductive layer 24 at the peripheral edge portion of the opening on one side of the through hole 21h.

An electrically conductive layer may also be formed on a second main surface (the lower surface in FIG. 2) of the insulating plate 22. An electrically conductive layer may also be formed in an intermediate layer of the insulating plate 22 in a thickness direction.

In the present embodiment, the through hole 21h is formed in a circular hole shape with recess-shaped portions formed in a non-continuous manner around the outer periphery. The through hole 21h will be described in further detail later in reference to the relationship with the metal member 30.

In the present embodiment, the element 50 is mounted on the first main surface of the metal member equipped circuit board 10. The element 50 is a component that generates heat, an example being a semiconductor switching element such as a field effect transistor (referred to as FET below), for example. The element may be a resistance, may be a coil, or may be a capacitor.

The element 50 is provided with an element body and a terminal. The terminal is provided on the side of the surface of the element body where the circuit board 20 is mounted. The portion of the electrically conductive layer 24 formed around the through hole 21h is formed in a shape corresponding with the terminal. For example, the terminal is provided in a region spread out in a rectangular shape, and the portion of the electrically conductive layer 24 formed around the through hole 21h is formed in a region spread out in a rectangular shape in the same manner as the terminal. The element 50 is mounted on the metal member equipped circuit board 10 with the entire terminal soldered to the electrically conductive layer 24.

The element 50 includes another terminal projecting from the element body. This other terminal is preferably soldered to another electrically conductive layer formed on the first main surface of the circuit board 20.

The metal member 30, for example, is formed of a metal, such as copper, a copper alloy, aluminum, an aluminum alloy, iron, stainless steel, or the like. The metal member 30 is arranged in the through hole 21h with a gap between it and the inner peripheral surface of the through hole 21h. Note that in a case where a layer is formed on the surface of the insulating plate 22 exposed in the through hole 21h, the inner peripheral surface of the through hole 21h corresponds to the surface of this layer. In this example, the electrically conductive layer 25 is formed on the surface of the insulating plate 22 exposed in the through hole 21h, and thus the inner peripheral surface of the through hole 21h corresponds to the surface of the electrically conductive layer 25.

In this example, the metal member 30 is provided with a body portion 32 and a head portion 34.

The body portion 32 is formed in a cylindrical shape. The height dimension of the body portion 32 is, for example, the same as the dimension of the through hole 21h in the axial direction or less than the dimension in the axial direction. Also, the body portion 32 is more narrow than the through hole 21h. The body portion 32 is inserted into the through hole 21h with the axial direction of the body portion 32 aligned with the axial direction of the through hole 21h.

The head portion 34 is contiguous with the base end (the lower side in FIG. 2) of the body portion 32. The head portion 34 is formed in a plate-like shape, a circular plate-like shape in this example, extending out from the outer periphery of the body portion 32. In a state in which the body portion 32 is inserted into the through hole 21h, the head portion 34 can be brought into contact with the second main surface of the circuit board 20 around the through hole 21h. In this manner, the metal member 30 is positioned in the thickness direction of the circuit board 20. The head portion 34 may have an elliptical plate-like shape or a polygon plate-like shape. The head portion 34 may be omitted.

The bonding member 40 is a member for bonding together the circuit board 20 and the metal member 30. An example of the bonding member 40 includes a solder, for example. The bonding member 40 may be a brazing filler material or an electrically conductive adhesive. In this example, the bonding member 40 is disposed between the metal member 30 and the through hole 21h and bonds together the circuit board 20 and the metal member 30. Also, in this example, the bonding member 40 is disposed between the leading end portion of the metal member 30 and the electrically conductive layer 24 and the terminal of the element 50, and the terminal of the element 50 is bonded to the metal member 30 and the electrically conductive layer 24.

The gap between the outer peripheral surface of the metal member 30 and the inner peripheral surface of the through hole 21h changes in the direction following the outer periphery of the metal member 30.

In this example, as described above, the outer peripheral surface of the body portion 32 of the metal member 30 is a cylindrical peripheral surface. In other words, the body portion 32 is circular as seen in the axial direction of the metal member 30.

Also, the inner peripheral surface of the through hole 21h includes a first circular hole peripheral surface portion 21h1 and a second circular hole peripheral surface portion 21h2.

The first circular hole peripheral surface portion 21h1 includes a non-continuous circular hole peripheral surface with the center of curvature being a center axis X of the metal member 30. In other words, the first circular hole peripheral surface portion 21h1 is constituted by the non-continuous inner peripheral surface of a circular hole that extends through the circuit board 20. The distance between the first circular hole peripheral surface portion 21h1 and the center axis X is greater than the radius of the body portion 32. Accordingly, an arc shaped gap of even width is formed between the outer peripheral surface of the body portion 32 and the first circular hole peripheral surface portion 21h1 in the direction following the outer periphery of the body portion 32. In the direction following the outer periphery of the body portion 32, a region R1 where the first circular hole peripheral surface portion 21h1 is formed is an even gap region R1 with a continuous portion with a constant gap between the outer peripheral surface of the metal member 30 and the inner peripheral surface of the through hole 21h.

The second circular hole peripheral surface portion 21h2 is formed in a non-continuous manner in the direction following the outer periphery of the body portion 32. The second circular hole peripheral surface portion 21h2 is a peripheral surface portion provided at a position separated from the center axis X further than the first circular hole peripheral surface portion 21h1. In this example, the second circular hole peripheral surface portion 21h2 is constituted by the non-continuous inner peripheral surface of a circular hole that extends through the circuit board 20. Accordingly, the through hole 21h can be described as a portion with a contiguous shape including inner peripheral surfaces of a plurality of circular through holes joined together. The through hole 21h, for example may be formed by forming a through hole at a position corresponding to the first circular hole peripheral surface portion 21h1 and a through hole at a position corresponding to the second circular hole peripheral surface portion 21h2 using a cutting tool for forming a circular hole.

The distance between the outer peripheral surface of the body portion 32 of the metal member 30 and the second circular hole peripheral surface portion 21h2 is greater than the distance between the outer peripheral surface of the body portion 32 and the first circular hole peripheral surface portion 21h1. Accordingly, in the direction following the outer periphery of the body portion 32, a region R2 where the second circular hole peripheral surface portion 21h2 is formed is a wide region R2 in which the gap between the outer peripheral surface of the metal member 30 and the inner peripheral surface of the through hole 21h is greater than the gap in the even gap region R1.

The even gap region R1 and the wide region R2 are disposed in a mixed arrangement in the direction following the outer periphery of the metal member 30. In this example, a plurality of the second circular hole peripheral surface portions 21h2 are provided, and thus a plurality of the wide regions R2 are provided at intervals in the direction following the outer periphery of the metal member 30. Also in this example, a plurality (4 in FIG. 1) of the second circular hole peripheral surface portions 21h2 (wide regions R2) are provided at equal intervals around the outer periphery of the metal member 30. The present embodiment is an example in which portions with a wide gap between the outer peripheral surface of the metal member 30 and the inner peripheral surface of the through hole 21h are provided evenly distributed in the direction following the outer periphery of the metal member 30.

The bonding member 40 disposed between the outer peripheral surface of the body portion 32 and the inner peripheral surface of the through hole 21h has the following mode, for example.

The bonding member 40 is embedded between the outer peripheral surface of the body portion 32 and the first circular hole peripheral surface portion 21h1. At this portion, there are few voids. In the space between the outer peripheral surface of the body portion 32 and the second circular hole peripheral surface portion 21h2, there may be the bonding member 40, but there is a void S. In other words, there are a larger number of voids S in the portion with the widest gap between the outer peripheral surface of the metal member 30 and the inner peripheral surface of the through hole 21h. It is likely that there is a void in the space between the outer peripheral surface of the body portion 32 and the first circular hole peripheral surface portion 21h1. However, there are preferably less voids, in terms of volume, here than in the space between the outer peripheral surface of the body portion 32 and the second circular hole peripheral surface portion 21h2. In other words, the bonding member 40 is disposed between the outer peripheral surface of the body portion 32 and the inner peripheral surface of the through hole 21h with a void S present, and the voids S are present more in the wide region R2 than in the even gap region R1. The voids S being present more in the wide region R2 than the even gap region R1 may be understood as meaning, for example, the volume of the voids in the wide region R2 is greater than the volume of the voids in the even gap region R1.

As described above, the bonding member 40 is also disposed between the leading end portion of the metal member 30 and the electrically conductive layer 24 and the terminal of the element 50. At this portion also, there are relatively few voids. In other words, the voids S are present more in the wide region R2 than in the region between the leading end portion of the metal member 30 and the electrically conductive layer 24 and the terminal. This bias may be understood as being similar to the bias of the voids S between the even gap region R1 and the wide region R2.

Note that the heat dissipation member 72 may be provided on the second main surface (the lower surface in FIG. 2) of the circuit board 20 with the thermally conductive member 70 disposed therebetween. The thermally conductive member 70 is, for example, an electrically conductive paste or the like including a mixture of a carbon filler, a mixture of a metal filler, or the like.

A method of manufacturing the metal member equipped circuit board 10 of the present embodiment will now be described.

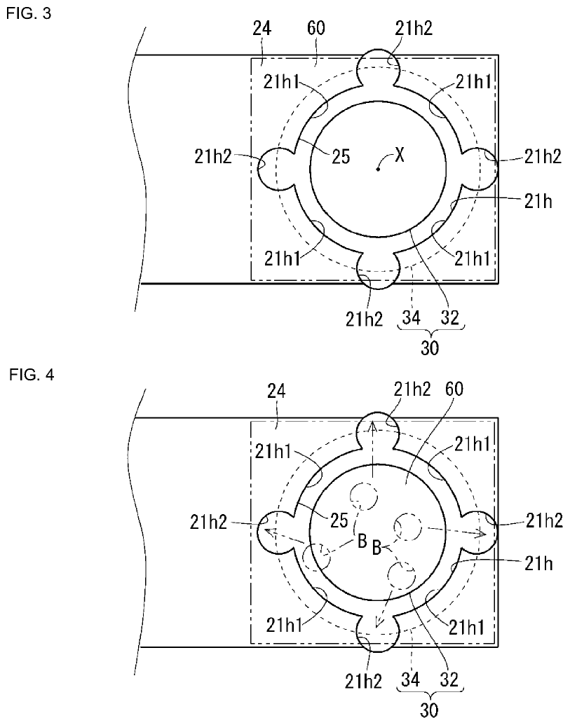

First, as illustrated in FIG. 3, the circuit board 20 in which the through hole 21h is formed is prepared. Next, a solder paste 60 is provided on the circuit board 20. The solder paste 60 is applied to or used to fill regions including the surface of the electrically conductive layer 24, the leading end surface of the metal member 30, the space between the inner peripheral surface of the through hole 21h and the outer peripheral surface of the metal member 30, and the like.

Then, with the element 50 placed on the circuit board 20, the solder paste 60 is heated and melted via a reflow process. The solder paste 60 includes a flux, and when the solder paste 60 is melted, the flux vaporizes. As illustrated in FIG. 4, the flux causes the formation of air bubbles B. Note that the element 50 is omitted in FIG. 4.

The air bubbles B are formed in each portion of the melted solder paste 60. Typically, the now liquid solder paste 60 has good wettability with respect to the surface of the electrically conductive layers 24, 25, the metal member 30, and the terminal of the element 50. Thus, the now liquid solder paste 60 seeps into the surface of the electrically conductive layers 24, 25 and the metal member 30 via capillary action.

In the even gap region R1, as the now liquid solder paste 60 seeps into the surface of the electrically conductive layer 25 (the surface of the through hole 21h) and the surface of the metal member 30, the air bubbles B are expelled from the even gap region R1 into the wide region R2.

The gap between the metal member 30 or the electrically conductive layer 24 and the terminal of the element 50 is relatively narrow. Thus, as the now liquid solder paste 60 seeps into the surface of the electrically conductive layer 24, the metal member 30, and the terminal of the element 50, the air bubbles B are expelled from the space between the metal member 30 or the electrically conductive layer 24 and the terminal into the relatively wide region R2.

In this manner, the air bubbles B are expelled into the wide region R2 via reflow process. Thereafter, when the melted solder hardens to form the bonding member 40, remnants of the air bubbles B form the voids S. As a result, in the even gap region R1, there are relatively few voids. Also, in the space between the metal member 30 or the electrically conductive layer 24 and the terminal of the element 50, there are relatively few voids S. On the other hand, in the wide region R2, there are relatively many voids S.

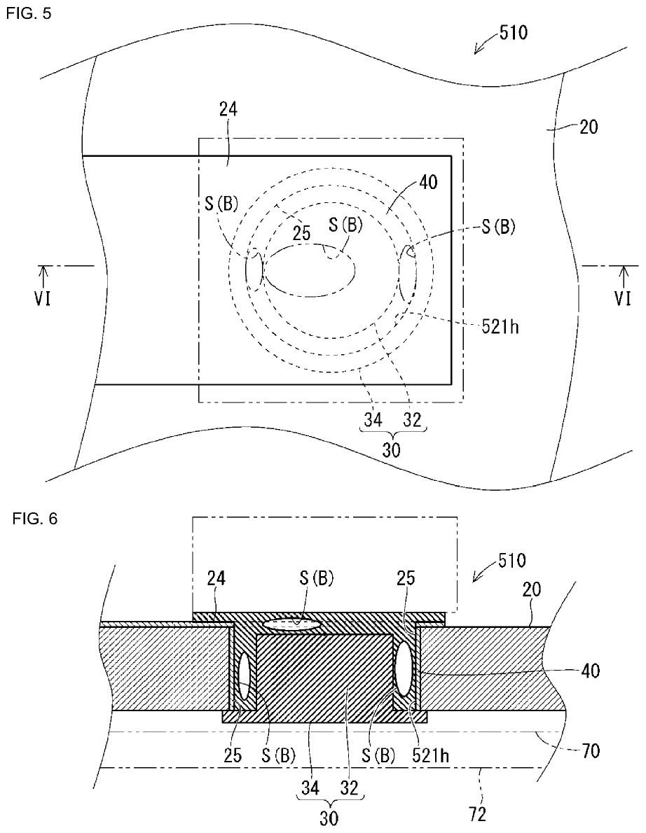

FIG. 5 is a schematic plan view illustrating a metal member equipped circuit board 510 according to a comparative example. FIG. 6 is a cross-sectional view taken along line VI-VI of FIG. 5. In the present comparative example, a through hole 521h corresponding to the through hole 21h is formed in a circular hole shape including an inner peripheral surface with a diameter greater than that of the outer peripheral surface of the metal member 30. Thus, a gap with an equal distance around the circumferential direction of the metal member 30 is formed in the space between the outer peripheral surface of the metal member 30 and the inner peripheral surface of the through hole 521h.

In this case, in the melted solder paste 60, the air bubbles B form at irregular positions. For example, in a case where the air bubbles B form in the space between the metal member 30 and the through hole 521h, the air bubbles B remain in place without moving to another position. Because the air bubbles B are formed at irregular positions, the voids S, i.e., remnants of the air bubbles B, are also formed at irregular positions. The air bubbles B are also formed in the space between the metal member 30 or the electrically conductive layer 24 and the terminal of the element 50. These air bubbles B also remain in place without moving. Accordingly, the voids S are also formed in the space between the metal member 30 or the electrically conductive layer 24 and the terminal.

The voids S also form in the space which should be filled in cases where the solder paste 60 is insufficient. However, the voids S formed because of this are, as described above, formed mainly in the wide region R2.

According to the metal member equipped circuit board 10 with this configuration, in the portion with a relatively narrow gap between the outer peripheral surface of the metal member 30 and the inner peripheral surface of the through hole 21h, the melted solder paste 60, i.e., the material that forms the bonding member 40, is put in the space between the outer peripheral surface and the inner peripheral surface, expelling the air bubbles B. On the other hand, in the portion with a relatively wide gap between the outer peripheral surface of the metal member 30 and the inner peripheral surface of the through hole 21h, the air bubbles B tend to remain. The remnants of the air bubbles B form the voids S. In particular, there are voids S in the portion with the widest gap between the outer peripheral surface of the metal member 30 and the inner peripheral surface of the through hole 21h. Thus, the position of the voids S in the bonding member 40 is significantly controlled. Because the position of the voids S is controlled to a degree, how the heat is transferred between the metal member 30 and the circuit board 20 is controlled to a degree. As a result, the thermal design and the like of the metal member equipped circuit board 10 is made easier.

Also, in this example, because the air bubbles B in the space between the metal member 30 or the electrically conductive layer 24 and the terminal of the element 50 are also expelled into the wide region R2, voids are unlikely to form in this space. Accordingly, heat generated at the element 50 is easily transferred to the metal member 30. The heat transferred to the metal member 30 is dissipated well via the thermally conductive member 70, the heat dissipation member 72, and the like.

Also, the good electrical conductivity from the metal member 30 to the electrically conductive layers 24, 25 as per the design is maintained due to controlling the position of the voids S.

Also, the even gap region R1 and the wide region R2 are disposed in a mixed arrangement in the direction following the outer periphery of the metal member 30. In the even gap region R1, a portion with a constant gap between the outer peripheral surface of the metal member 30 and the inner peripheral surface of the through hole 21h is continuously provided. Thus, in the entire even gap region R1, the air bubbles B can be easily expelled in as uniform a mode as possible. Also, the expelled air bubbles B tend to gather in the wide region R2 and remain there. As a result, a region with as few voids as possible and a region with many voids S should be divided.

Also, portions with a wide gap between the outer peripheral surface of the metal member 30 and the inner peripheral surface of the through hole 21h are provided evenly distributed in the direction following the outer periphery of the metal member 30. In this example, the plurality of (four) wide regions R2 are provided at equal intervals around the metal member 30. Accordingly, for example, the air bubbles formed around the metal member are unlikely to be have positional relationship with the wide region of being located far apart such as being located on the opposite side of the metal member from the wide region. As a result, the air bubbles B formed around the metal member 30 or in the entire leading end side are easily expelled to one of the wide regions R2. Thus, the voids S tend to be concentrated in the wide regions R2.

Also, the inner peripheral surface of the even gap region R1 and the inner peripheral surface of the wide region R2 are formed as the non-continuous inner peripheral surface of the circular hole extending through the circuit board 20. The inner peripheral surface of the wide region R2 can be easily formed using a cutting tool (a drill bit or the like) or the like for forming a circular through hole.

### Second Embodiment

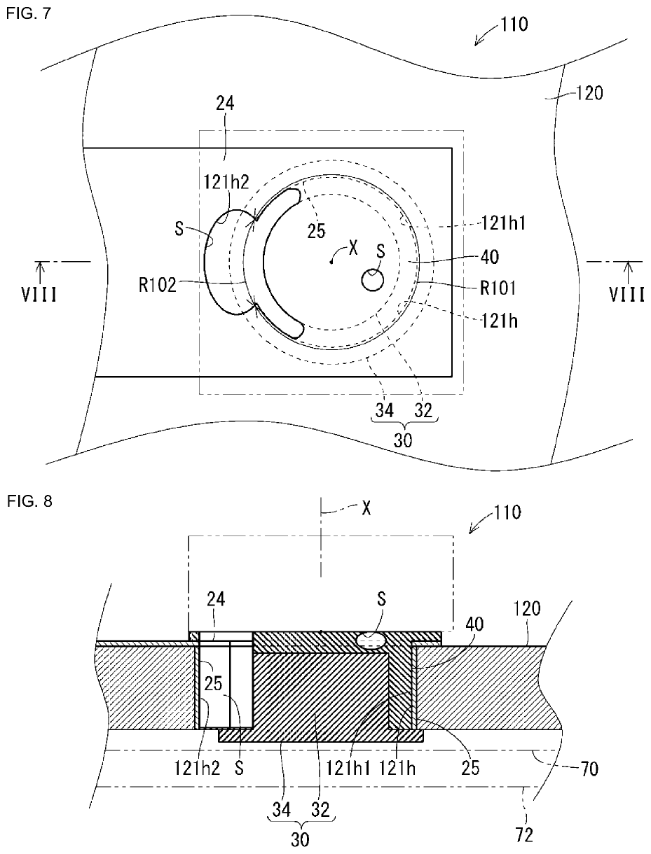

A metal member equipped circuit board according to the second embodiment will now be described. FIG. 7 is a schematic plan view illustrating a metal member equipped circuit board 110. FIG. 8 is a cross-sectional view taken along line XIII-XIII of FIG. 7. In FIGS. 7 and 8, the element 50 mounted on the metal member equipped circuit board 110 is indicated by a two-dot dash line. In FIG. 8, the heat dissipation member 72 and the thermally conductive member 70 are indicated by a two-dot dash line. Note that in the description of the present second embodiment, components similar to that described in the first embodiment are given the same reference sign and description thereof will be omitted. The metal member equipped circuit board 110 according to the second embodiment will be described below focusing on the portions that are different from those of the metal member equipped circuit board 10 according to the first embodiment.

A through hole 121h according to the second embodiment corresponds to the through hole 21h. The inner peripheral surface shape of the through hole 121h is different from the inner peripheral surface shape of the through hole 21h.

The inner peripheral surface of the through hole 121h includes a first circular hole peripheral surface portion 121h1 and a second peripheral surface portion 121h2.

The first circular hole peripheral surface portion 121h1 includes a non-continuous circular hole peripheral surface with the center of curvature being the center axis X of the metal member 30. The distance between the first circular hole peripheral surface portion 121h1 and the center axis X is greater than the radius of the body portion 32. Accordingly, the distance between the outer peripheral surface of the body portion 32 and the first circular hole peripheral surface portion 121h1 in the direction following the outer periphery of the body portion 32 is constant. In the direction following the outer periphery of the body portion 32, a region R101 where the first circular hole peripheral surface portion 121h1 is formed is an even gap region R101 with a continuous portion with a constant gap between the outer peripheral surface of the metal member 30 and the inner peripheral surface of the through hole 121h.

The second peripheral surface portion 121h2 is formed in a non-continuous manner in the direction following the outer periphery of the body portion 32. The second peripheral surface portion 121h2 is a peripheral surface portion provided at a position separated from the center axis X further than the first circular hole peripheral surface portion 121h1. In this example, the second peripheral surface portion 121h2 is constituted by the non-continuous inner peripheral surface of an elliptical hole that extends through a circuit board 120. Accordingly, the through hole 121h can be described as a portion with a contiguous shape including inner peripheral surfaces of a circular through hole and an elliptical through hole joined together. In a case where the second peripheral surface portion 121h2 is a shape formed by moving the locus of a circle, the second peripheral surface portion 121h2 can be easily formed using a cutting tool for forming a circular hole.

The distance between the outer peripheral surface of the body portion 32 of the metal member 30 and the second peripheral surface portion 121h2 is greater than the distance between the outer peripheral surface of the body portion 32 and the first circular hole peripheral surface portion 121h1. Accordingly, in the direction following the outer periphery of the body portion 32, a region R102 where the second peripheral surface portion 121h2 is formed is a wide region R102 in which the gap between the outer peripheral surface of the metal member 30 and the inner peripheral surface of the through hole 121h is greater than the gap in the even gap region R101.

The even gap region R101 and the wide region R102 are disposed in a mixed arrangement in the direction following the outer periphery of the metal member 30. In this example, only one second peripheral surface portion 121h2 is provided, and thus only one wide region R102 is provided. The present embodiment is an example in which a portion with a wide gap between the outer peripheral surface of the metal member 30 and the inner peripheral surface of the through hole 121h is provided in an unevenly distributed manner in the direction following the outer periphery of the metal member 30.

In a case where a plurality of the second circular hole peripheral surface portions and the wide regions are provided, a portion with a wide gap between the outer peripheral surface of the metal member and the inner peripheral surface of the through hole may be provided in an unevenly distributed manner. For example, a plurality of second circular hole peripheral surface portions (or a plurality of wide regions) may be provided at unequal intervals around the outer periphery of the metal member and concentrated in one portion around the outer periphery of the metal member. In this case, the plurality of second circular hole peripheral surface portions (or the plurality of wide regions) may be provided within an area formed by a center angle of less than 180 degrees with respect to the center axis X of the metal member, or may be provided within an area formed by a center angle of less than 90 degrees with respect to the center axis X.

The bonding member 40 disposed between the outer peripheral surface of the body portion 32 and the inner peripheral surface of the through hole 121h has the following mode, for example.

The bonding member 40 is embedded between the outer peripheral surface of the body portion 32 and the first circular hole peripheral surface portion 121h1. At this portion, there are few voids. In the space between the outer peripheral surface of the body portion 32 and the second peripheral surface portion 121h2, there may be the bonding member 40, but there is a void S. There is also a likelihood that voids are present in the space between the outer peripheral surface of the body portion 32 and the first circular hole peripheral surface portion 121h1. For example, in a case where the voids S are large, the voids S may be formed spanning from the wide region R102 to the end portion of the even gap region R101. However, in this case also, there are preferably less voids, in terms of volume, in the even gap region R101 than in the space between the outer peripheral surface of the body portion 32 and the second peripheral surface portion 121h2. In other words, the bonding member 40 is disposed between the outer peripheral surface of the body portion 32 and the inner peripheral surface of the through hole 121h with a void S present, and the voids S are present more in the wide region R102 than in the even gap region R101. In a similar manner to the first embodiment, the voids S being present more in the wide region R102 than the even gap region R101 may be understood as meaning, for example, the volume of the voids in the wide region R102 is greater than the volume of the voids in the even gap region R101.

As described above, the bonding member 40 is also disposed between the leading end portion of the metal member 30 and the electrically conductive layer 24 and the terminal of the element 50. At this portion also, there are relatively few voids. In other words, the voids S are present more in the wide region R102 than in the region between the leading end portion of the metal member 30 and the electrically conductive layer 24 and the terminal. This bias may be understood as being similar to the bias of the voids S between the even gap region R101 and the wide region R102.

An example of how the voids S are formed in the manufacture of the metal member equipped circuit board 110 will now be described.

In a similar manner to FIG. 3 of the first embodiment described above, the circuit board 120 is prepared. Next, the solder paste 60 is provided on the circuit board 120. The solder paste 60 is applied to or used to fill the surface of the electrically conductive layer 24, the leading end surface of the metal member 30, the space between the inner peripheral surface of the through hole 121h and the outer peripheral surface of the metal member 30, and the like.

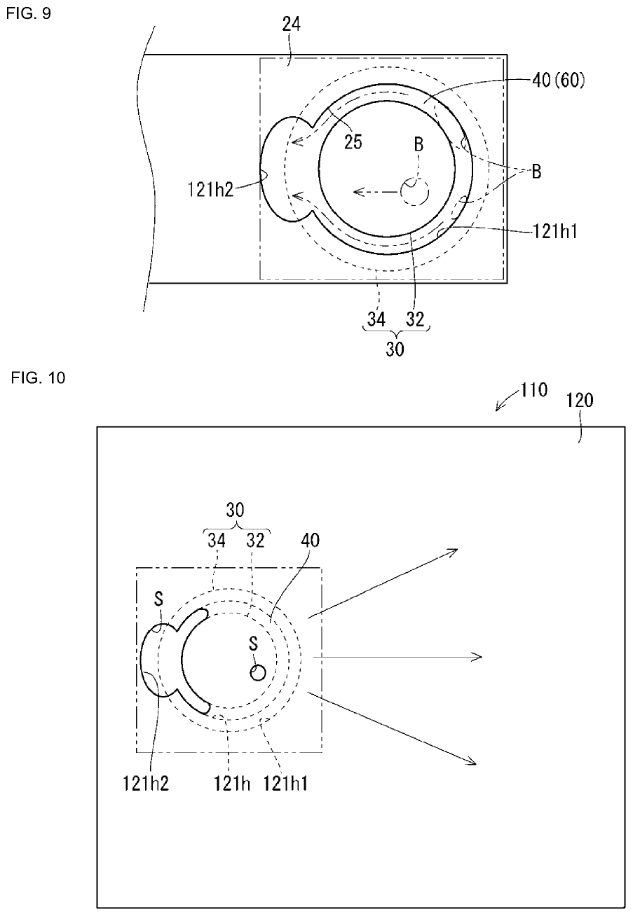

Then, with the element 50 placed on the circuit board 120, the solder paste 60 is melted via a reflow process. Here, as illustrated in FIG. 9, the flux causes the formation of air bubbles B. Note that the element 50 is omitted in FIG. 9.

The air bubbles B are formed in each portion of the melted solder paste 60. In a similar manner to the first embodiment described above, the now liquid solder paste 60 seeps into the surface of the electrically conductive layers 24, 25 and the metal member 30.

In the even gap region R101, as the now liquid solder paste 60 seeps into the surface of the electrically conductive layer 25 (the inner peripheral surface of the through hole 121h) and the surface of the metal member 30, the air bubbles B are expelled from the even gap region R101 into the wide region R102.

The gap between the metal member 30 or the electrically conductive layer 24 and the terminal of the element 50 is relatively narrow. Thus, as the now liquid solder paste 60 seeps into the surface of the electrically conductive layer 24, the metal member 30, and the terminal, the air bubbles B are expelled from the space between the metal member 30 or the electrically conductive layer 24 and the terminal into the relatively wide region R102.

In this manner, the air bubbles B are expelled to the wide region R102 side via reflow process. Thereafter, when the melted solder hardens to form the bonding member 40, remnants of the air bubbles B form the voids S. As a result, in the even gap region R101, there are relatively few voids. Also, in the space between the metal member 30 or the electrically conductive layer 24 and the terminal of the element 50, there are relatively few voids S. On the other hand, in the wide region R102, there are relatively many voids S.

According to the metal member equipped circuit board 110 with this configuration, in a similar manner to the first embodiment described above, the position of the voids S is controlled to a degree so that there are as few voids S in the even gap region R101 as possible and as many voids S in the wide region R102 as possible. This allows how the heat is transferred between the metal member 30 and the circuit board 120 to be controlled to a degree. As a result, the thermal design and the like of the metal member equipped circuit board 110 is made easier.

Also, in a similar manner to the first embodiment, because the air bubbles B in the space between the metal member 30 or the electrically conductive layer 24 and the terminal of the element 50 are also expelled into the wide region R102, voids are unlikely to form in this space. Accordingly, heat generated at the element 50 is easily transferred to the metal member 30. The heat transferred to the metal member 30 is dissipated well via the thermally conductive member 70, the heat dissipation member 72, and the like.

Also, the even gap region R101 and the wide region R102 are disposed in a mixed arrangement in the direction following the outer periphery of the metal member 30. In a similar manner to the first embodiment, a region with as few voids as possible and a region with many voids S should be divided.

Also, a portion with a wide gap between the outer peripheral surface of the metal member 30 and the inner peripheral surface of the through hole 121h, i.e., the wide region R102, is provided in an unevenly distributed manner in the direction following the outer periphery of the metal member 30. Thus, it is easy to form a section in which the voids S are unevenly distributed in the direction following the outer periphery of the metal member 30. This makes it easy to control how big or small the thermal resistance is around the outer periphery of the metal member 30. For example, as illustrated in FIG. 10, the arrangement position of the metal member 30 in relation to the entire circuit board 120 corresponding to the circuit board 20 is not in a central position of the circuit board 20 but offset to one side. In this case, to increase heat dissipation, the heat is preferably transferred to a side (the right side in FIG. 10) where the circuit board 120 has a wide area expanding away from the metal member 30. Accordingly, the position of the wide region R102 with respect to the metal member 30 is preferably on the opposite side to the side where the circuit board 120 is expansive. In this case, the voids S are mainly formed on the wide region R102 side. On the side where the circuit board 120 has a wide area expanding away from the metal member 30, in a state with few voids S, the metal member 30 is bonded to the circuit board 120 via the bonding member 40. Thus, the heat at the metal member 30 easily transfers to the expansive side of the circuit board 120 via the bonding member 40. In this way, heat is efficiently dissipated. More specifically, the heat generated at the element 50 is transferred from the metal member 30 to the expansive side of the circuit board 120 via the bonding member 40, and the heat is easily dissipated.

Also, in the example envisioned here, the element 50 and the metal member 30 are connected to the electrically conductive layer of the circuit board 120, and the electrically conductive layer is drawn out in one direction from the element 50 and the metal member 30. In this case, the wide region R102 is preferably provided on the side opposite the side where the electrically conductive layer is drawn out. In this manner, the element 50 and the metal member 30 and the electrically conductive layer are connected in a state in which there are few voids and there is low electrical resistance on the side where the electrically conductive layer is drawn out.

### Modified Example

The shape of the through holes 21h, 121h is not limited to that described in the examples above.

For example, in a first modified example illustrated in FIG. 11, a through hole 221h is formed in an elliptical hole shape, and the metal member 30 including the cylindrical body portion 32 may be inserted into the through hole 221h in a central region in the long axis direction. In this case, a wide region R202 with the widest gap is provided at both ends in the long axis direction of the through hole 221h. At both ends in the short axis direction, the gap between the outer peripheral surface of the body portion 32 and the inner peripheral surface of the through hole 221h is the most narrow. As illustrated in FIG. 11, regarding the portion where the gap between the outer peripheral surface of the body portion 32 and the inner peripheral surface of the through hole 221h is the most narrow, the outer peripheral surface of the body portion 32 and the inner peripheral surface of the through hole 221h may be in contact with one another.

In this case, the voids S are formed offset from the middle at both ends in the long axis direction of the through hole 221h. In this manner, the position of the voids S is controlled. The present first modified example is an example in which portions with a wide gap between the outer peripheral surface of the metal member 30 and the inner peripheral surface of the through hole 221h are provided evenly distributed in the direction following the outer periphery of the metal member 30.

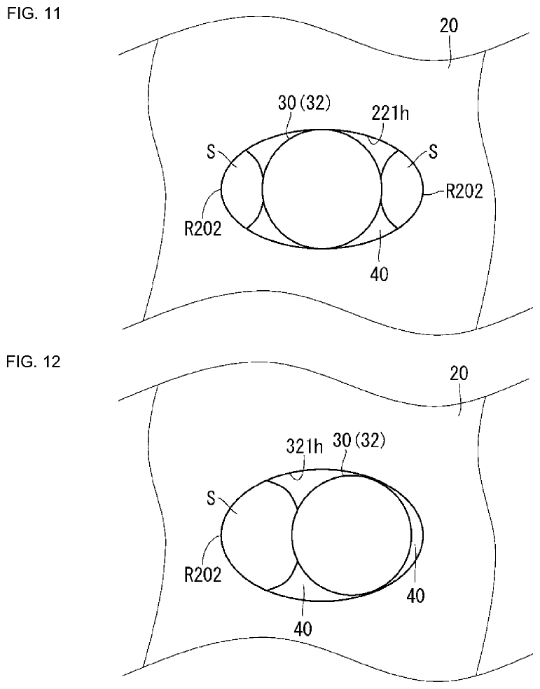

For example, as illustrated in a second modified example illustrated in FIG. 12, the metal member 30 including the cylindrical body portion 32 may be inserted into a through hole 321h offset from the middle. In this example, the through hole 321h is formed in an elliptical hole shape. The body portion 32 is disposed at a position offset to one end side in the long axis direction of the through hole 321h.

In this case, a wide region R302 with the widest gap is provided at one end side in the long axis direction of the through hole 321h.

In this case, the void S is offset from the middle toward one end side in the long axis direction of the through hole 321h. In this manner, the position of the void S is controlled. The present second modified example is an example in which a portion with a wide gap between the outer peripheral surface of the metal member 30 and the inner peripheral surface of the through hole 321h is provided unevenly distributed in the direction following the outer periphery of the metal member 30.

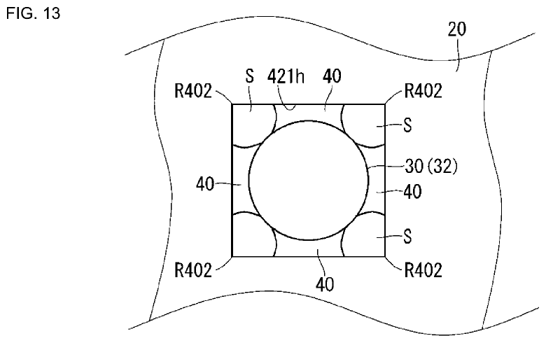

For example, in a third modified example illustrated in FIG. 13, the metal member 30 including the cylindrical body portion 32 may be inserted into a through hole 421h that is not a circular hole. In this example, the through hole 421h is formed in a quadrangular (square in this example) shape. The center axis of the body portion 32 and the center axis of the through hole 421h coincide with one another.

In this case, a wide region R402 with the widest gap is provided at each corner portion of the through hole 421h.

In this case, the voids S are formed at or near the corner portions of the through hole 421h. In this manner, the position of the void S is controlled. The present third modified example is an example in which portions with a wide gap between the outer peripheral surface of the metal member 30 and the inner peripheral surface of the through hole 421h are provided evenly distributed in the direction following the outer periphery of the metal member 30.

In the embodiments and modified examples described above, the body portion 32 of the metal member 30 is cylindrical. However, the body portion 32 is not necessarily cylindrical. For example, in a configuration in which the body portion is inserted into a circular through hole, the body portion inserted may have a cylindrical shape that is recessed in a non-continuous manner around the outer peripheral portion of the cylindrical shape. In this case, in the region where a recess portion is formed, the gap between the outer peripheral surface of the metal member and the inner peripheral surface of the through hole is increased, making it more likely that a void is formed in this portion.

In another possible configuration, a metal member with a polygonal shape may be inserted into a through hole with a circular hole or elliptical hole shape, and, in the direction following the outer periphery of the metal member, the gap between the outer peripheral surface of the metal member and the inner peripheral surface of the through hole may vary.

Note that, even in a case where the bonding member is formed using a brazing filler material or an electrically conductive adhesive, voids formed from air bubbles may still be a problem. Thus, even in a case where the bonding member is formed using a brazing filler material or an electrically conductive adhesive, the configurations described above are effective.

Note that the configurations described in the embodiments and the modified examples can be appropriately combined with one another in a non-contradictory manner.

1. A metal member equipped circuit board, comprising:
a circuit board in which a through hole is formed;
a metal member disposed in the through hole in a state of forming a gap between the metal member and an inner peripheral surface of the through hole; and
a bonding member that bonds together the circuit board and the metal member, wherein
in a direction following an outer periphery of the metal member, a gap between an outer peripheral surface of the metal member and the inner peripheral surface of the through hole varies, and a void is present in a portion with a widest gap between the outer peripheral surface of the metal member and the inner peripheral surface of the through hole.

2. The metal member equipped circuit board according to claim 1, wherein in the direction following the outer periphery of the metal member, an even gap region with a continuous portion with a constant gap between the outer peripheral surface of the metal member and the inner peripheral surface of the through hole and a wide region in which a gap between the outer peripheral surface of the metal member and the inner peripheral surface of the through hole is greater than the gap in the even gap region are arranged in a mixed pattern.

3. The metal member equipped circuit board according to claim 1, wherein in the direction following the outer periphery of the metal member, portions with a wide gap between the outer peripheral surface of the metal member and the inner peripheral surface of the through hole are provided evenly distributed.

4. The metal member equipped circuit board according to claim 1, wherein in the direction following the outer periphery of the metal member, portions with a wide gap between the outer peripheral surface of the metal member and the inner peripheral surface of the through hole are provided unevenly distributed.

5. The metal member equipped circuit board according to claim 2, wherein at least a portion of the inner peripheral surface formed the through hole is a non-continuous inner peripheral surface of a circular hole that extends through the circuit board.

6. The metal member equipped circuit board according to claim 2, wherein in the direction following the outer periphery of the metal member, portions with a wide gap between the outer peripheral surface of the metal member and the inner peripheral surface of the through hole are provided evenly distributed.

7. The metal member equipped circuit board according to claim 2, wherein in the direction following the outer periphery of the metal member, portions with a wide gap between the outer peripheral surface of the metal member and the inner peripheral surface of the through hole are provided unevenly distributed.

8. The metal member equipped circuit board according to claim 3, wherein at least a portion of the inner peripheral surface formed the through hole is a non-continuous inner peripheral surface of a circular hole that extends through the circuit board.

9. The metal member equipped circuit board according to claim 4, wherein at least a portion of the inner peripheral surface formed the through hole is a non-continuous inner peripheral surface of a circular hole that extends through the circuit board.
